(19) United States
(12) Patent Application Publication
(10) Pub. No.: US 2011/0221455 A1
(43) Pub. Date: Sep. 15, 2011

(54) MICROMECHANICAL COMPONENT AND METHOD FOR ITS PRODUCTION

(75) Inventor: Ando Feyh, Palo Alto, CA (US)

(73) Assignee: ROBERT BOSCH GMBH, Stuttgart (DE)

(21) Appl. No.: 13/119,695

(22) PCT Filed: Aug. 3, 2009
(86) PCT No.: PCT/EP2009/060025

§ 371 Date: May 26, 2011

(30) Foreign Application Priority Data
Sep. 25, 2008 (DE) 102008042350.5

(51) Int. Cl. G01R 27/26; H05K 3/36

(52) U.S. Cl. 324/661; 29/830

(57) ABSTRACT

A method for producing a micromechanical component, includes providing a first substrate, developing a micropattern on the first substrate, the micropattern having a movable functional element, providing a second substrate, and developing an electrode in the second substrate for the capacitive recording of a deflection of the functional element. The method further includes connecting the first and the second substrate, a closed cavity being formed which encloses the functional element, and the electrode bordering on the cavity in an area of the functional element.

### FIELD OF THE INVENTION

The present invention relates to a micromechanical component having a first substrate and a second substrate that is connected to the first substrate, the first substrate having a micropattern having a movable functional element, and the first and the second substrate being connected to each other in such a way that the functional element is enclosed by a cavity. Furthermore, the present invention relates to a method for manufacturing such a component.

### BACKGROUND INFORMATION

Micromechanical components, which are used, in the automotive field, as inertial and acceleration sensors, for example, normally have a micropattern having a movable functional element. The micropattern is also designated as a MEMS structure (microelectromechanical system). During the operation of the sensors, the deflection of a functional element is detected, for instance, by a change in the electrical capacity compared to a fixed reference electrode.

A common method for producing a micromechanical component includes forming the micropattern on a functional substrate, and connecting the functional substrate to a cap substrate by a so-called wafer bonding method. A cavity is formed, in this manner, which encloses the functional element, whereby the functional element is sealed hermetically from the environment. Besides the micropattern, buried printed circuit traces are also formed in the functional substrate, which are situated below the functional pattern. These may be used as electrodes for the capacitive recording of the deflection of functional elements, as well as providing an electrical path to contact elements (bondpads) outside the frame-shaped cap. The cap of the functional substrate is usually carried out in a specified gas and pressure atmosphere, in order to set a corresponding pressure atmosphere in the cavity. As the adhesive for connecting the functional substrate and the cap substrate, seal glass (solder glass) is used, which is applied onto the substrate with the aid of a screen-printing technique, for instance.

This construction of the component is connected to a series of disadvantages. The development of the buried printed circuit traces, which lead to contact elements next to the MEMS structure and outside the cap, results in a large surface requirement of the component. Furthermore, the method is complex, and requires a large number of process steps. For example, the method may bring along with it the use of more than ten lithographic patterning planes and lithographic patterning methods, whereby high production costs come about for the entire process. Critical process steps are also found in the method sequence which may lead, for instance, to the under-etching of a buried printed circuit trace. Moreover, the use of seal glass leads to a relatively wide bonding frame, which further increases the size of the component. In addition, the seal glass is laced with a solvent during its application, which has to be driven off during the bonding method. The problem is, however, that a residual portion of the solvent is able to remain behind in the seal glass, and be liberated into the cavity and change the specified pressure.

### SUMMARY OF THE INVENTION

It is an object of the exemplary embodiments and/or exemplary methods of the present invention to state an improved method for producing a micromechanical component and an improved micromechanical component, in which the abovementioned disadvantages are avoided.

This object is attained by a method as described herein and by a micromechanical component as described herein. Further advantageous developments of the exemplary embodiments and/or exemplary methods of the present invention are further described herein.

A method for manufacturing such a component is also provided, according to the present invention. The method includes providing a first substrate and developing a micropattern on the first substrate, the micropattern having a movable functional element. The method also includes providing a second substrate and developing an electrode in the second substrate for the capacitive detection of a deflection of the functional element. The first and the second substrate are connected, a closed cavity being formed which encloses the functional substrate, and the electrode bordering on the cavity in an area of the functional element.

Since the second substrate has an electrode for the capacitive detection of a deflection of the functional element, one may do without the development of a buried printed circuit trace in the first substrate and a contact element connected to the printed circuit trace that is laterally offset with respect to the micropattern. As a result, the micromechanical component is able to be realized using a small component size. Then too, one is able to produce the component using a relatively small number of patterning planes, or rather, process steps, whereby the method becomes simple and cost-effective. Furthermore, there are no critical process steps having negative consequences, such as the under-etching of printed circuit traces mentioned above, so that also no costly measures are required for preventing such effects.

According to one specific embodiment, the development of the electrode includes the developing of an insulation structure in the second substrate. A substrate area is framed in the second substrate via the insulation structure, which is used as an electrode.

According to one additional specific embodiment, the micropattern is developed having a first metallic layer. A second metallic layer is developed on the second substrate. Connecting the first and second substrate takes place via the first and second metallic layer. This makes possible a hermetically sealed and space-saving connection between the two substrates. There is also no danger of the liberation of gas, whereby the cavity is able to be developed to have a very low and specified pressure. A connecting method that may be used is eutectic bonding or thermal compression bonding.

According to a further specific embodiment, after the connection of the first and second substrate, substrate material is removed on a backside surface of the second substrate, in order to expose the electrode on the backside surface, so that it is able to be contacted from outside. Since the removing of substrate material is carried out only after connecting the substrates, the second substrate may have a relatively large thickness in the preceding method steps, whereby it is easier to carry out the method. After the removal of the substrate material, one may further develop a metallization on the backside surface of the second substrate, which contacts the exposed electrode.

According to one additional specific embodiment, a terminal passing through the second substrate is developed in the second substrate. An electrical connection to the micropattern may be produced, passing through the second substrate, via the terminal.

A micromechanical component is also proposed, according to the present invention. The component has a first substrate and a second substrate connected to the first substrate. The first substrate has a micropattern having a movable functional element. The first and the second substrate are connected to each other in such a way that the functional element is enclosed by a closed cavity. The micromechanical component is distinguished in that the second substrate has an electrode for the capacitive detection of a deflection of the functional element, the electrode bordering on the cavity in the area of the functional element. Because of the situation of the electrode in the second substrate, the component is able to be produced in a simple and cost-effective manner, and having a small size.

In the following text, the exemplary embodiments and/or exemplary methods of the present invention will be explained in greater detail with reference to the figures.

### BRIEF DESCRIPTION OF THE DRAWINGS

FIG. 1 shows a method for producing a micromechanical component, in a lateral sectional view.

FIG. 2 shows a method for producing a micromechanical component, in another lateral sectional view.

FIG. 3 shows a method for producing a micromechanical component, in another lateral sectional view.

FIG. 4 shows a method for producing a micromechanical component, in another lateral sectional view.

FIG. 5 shows a method for producing a micromechanical component, in another lateral sectional view.

FIG. 6 shows a method for producing a micromechanical component, in another lateral sectional view.

FIG. 7 shows a method for producing a micromechanical component, in another lateral sectional view.

### DETAILED DESCRIPTION

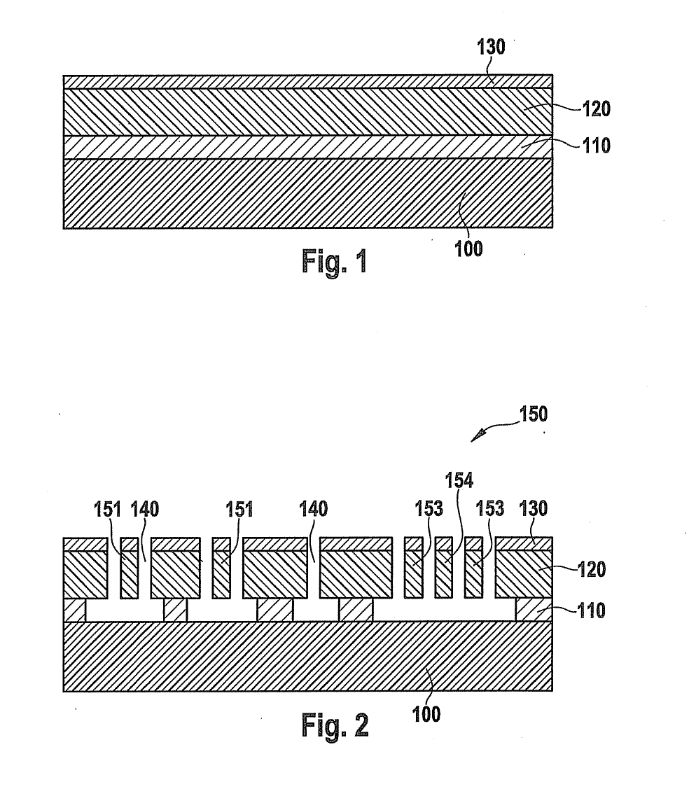

The following FIGS. 1 through 7 schematically show the production of a micromechanical component 300 which, for example, may be used as an inertial sensor in a motor vehicle. The usual processes and materials that are customary in semiconductor technology may be used in the production.

FIGS. 1 and 2 show the production of a functional substrate 100 having a micromechanical or MEMS structure 150 for component 300. At the beginning, a substrate 100 is provided, which has a semiconductor material such as silicon, for example. Substrate 100 may be a customary wafer having a diameter of 8 inches (20.0 mm).

Subsequently, as shown in FIG. 1, a sacrificial layer 110 is applied onto substrate 100 and a functional layer 120 is applied onto sacrificial layer 110. Sacrificial layer 110 may have silicon oxide. Functional layer 120 may be a so-called epi-polysilicon layer, that is, a polycrystalline silicon layer produced in an epitaxy method. Functional layer 120 may optionally be developed additionally to be doped, in order to increase the electrical conductivity and/or to provide layer 120 with a specified mechanical stress. The construction of substrate 100 with the layers 110, 120 may alternatively be implemented by a so-called SOI substrate (silicon on insulator), functional layer 120 being able to have monocrystalline silicon, in this case.

As shown in FIG. 1, a thin metallic layer 130 is applied onto functional layer 120, in addition. Metallic layer 130 may have a thickness in a range such as some 10 nm up to a few micrometers. Metals such as aluminum, copper and gold come into consideration as the material for layer 130. The use of a metal alloy such as an aluminum-silicon-copper alloy is also possible.

As shown in FIG. 2, metallic layer 130 is patterned. In this instance, a lithographic patterning method is carried out, in which first a patterned photoresist layer is produced on metallic layer 130, and metallic layer 130 is submitted to an etching method of the pattern. Patterned metallic layer 130 is subsequently used as a mask for etching trenches 140 into functional layer 120. The shape of a micropattern 150, that is to be developed, is established via trenches 140. The trench etching may be carried out, for example, with the aid of a DRIE method (deep reactive ion etching), in which an anisotropically acting etching plasma is used.

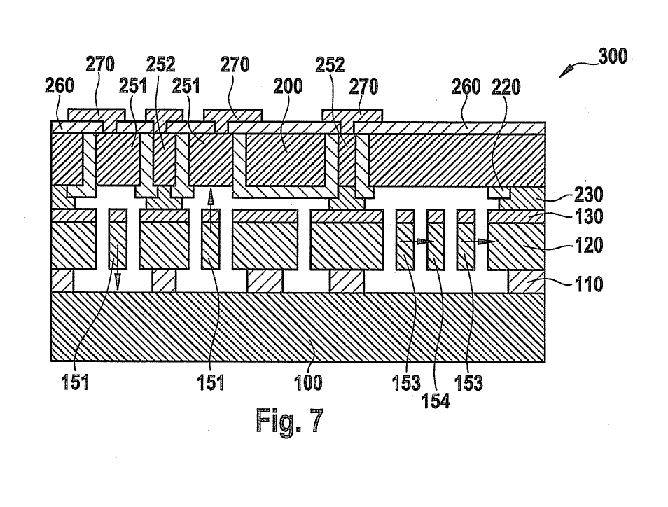

In order to complete micropattern 150, a part of sacrificial layer 110 is additionally removed, in order to expose electrode fingers or functional elements 151, 153, 154 as shown in FIG. 2. For this purpose, an etching medium or etching gas is brought in to sacrificial layer 110 via trenches 140. In case sacrificial layer 110 has silicon oxide, as described above, hydrofluoric acid vapor may be used for this, for example. Functional elements 151 form a so-called z rocker, and are thus developed for deflection perpendicular to the substrate surface (z direction). Functional elements 153, 154 form an oscillator structure or comb structure, functional element 154 being immobile and functional elements 153 being deflectable parallel to the substrate surface (“x/y direction”) (cf. FIG. 7).

After the etching of sacrificial layer 110, substrate 100 having micropattern 150 is essentially ready. Substrate 100 is therefore designated below as functional substrate 100. Since only one lithographic patterning is carried out, the production of functional substrate 100 is connected with a relatively low cost.

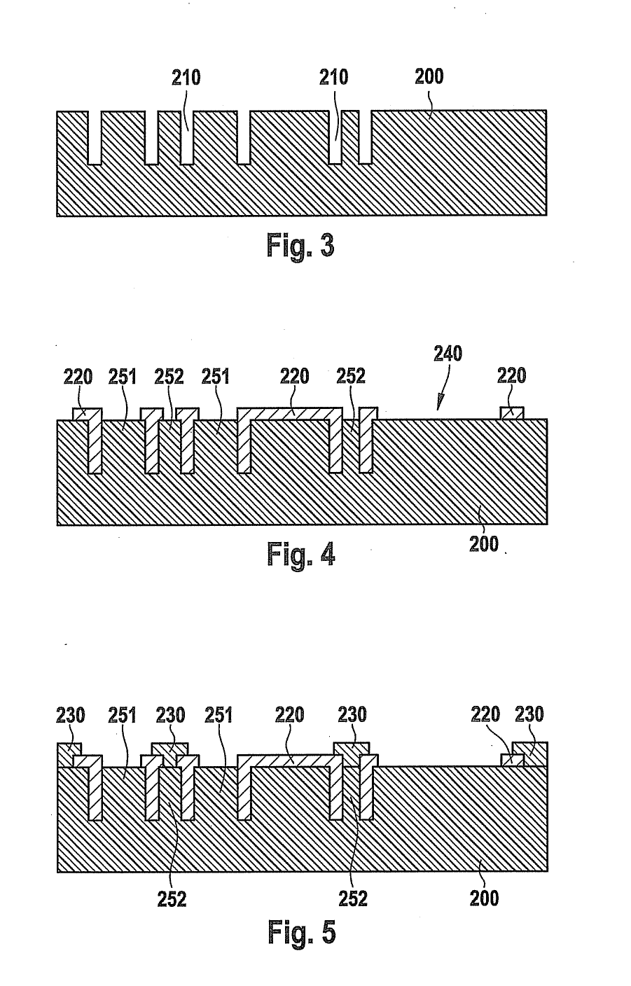

FIGS. 3 to 5 show the production of a cap substrate 200, which is connected to functional substrate 100 to develop micromechanical component 300. In this case, cap substrate 200 is used not only for hermetically sealing functional elements 151, 153, 154, but is also used for capacitive coupling and electrical contacting. A substrate 200 is first supplied which may have a semiconductor material such as silicon. Substrate 200 may also be a wafer having a diameter of 8 inches, for instance.

In substrate 200 supplied, trenches 210, shown in FIG. 3, are developed which, as described below, are used for insulation and for the definition of substrate regions for capacitive and electrical coupling. To develop trenches 210, an appropriate lithographic method and an etching method (such as a DRIE method) may be carried out. Trenches 210 have a depth of some 10 μm to a few 100 μm, for example.

After that, an insulating layer 220 is applied over a large area onto substrate 200, while filling up trenches 210. Insulating layer 220 has an oxide, for instance, or alternatively another dielectric material, such as a nitride. Within the scope of an additional lithographic patterning method, insulating layer 220 is patterned, so that the shape shown in FIG. 4 comes about, in which the semiconductor material of substrate 200 is exposed in partial sections.

Substrate areas are framed or defined, via insulating layer 220 that is situated in trenches 210, and they are used in micromechanical component 300 as electrodes 251 for the capacitive evaluation and as terminals 252 for the electrical contacting. Furthermore, a recess or cavity is defined in the area of an electrode 251 by patterned layer 220 on the surface of the substrate, which makes possible the motion of a functional element 151 in the direction of electrode 251. A corresponding cavity or topography 240, defined by layer 220, is also provided at another section of substrate 200, so that an unimpeded motion of functional elements 153 in the x/y direction is made possible, that is, perpendicular to the direction of motion of a functional element 151.

In order to increase the electrical conductivity of electrodes 251 and terminals 252, doping of substrate 200 is able to take place optionally, before or after the production of trenches 210 and the development of patterned insulating layer 220. For this purpose, for instance, a phosphorus glass (POC13) may be applied onto substrate 200 and subsequently a temperature step may be carried out so as to introduce phosphorus into substrate 200 as doping substance.

A metallic layer 230 is subsequently applied onto substrate 200 or layer 220 and is patterned with the aid of a lithographic patterning method, so that cap substrate 200 is essentially ready (FIG. 5). With respect to possible materials for metallic layer 230, we refer to the above statements on metallic layer 130 of functional substrate 100. A part of metallic layer 230 is situated on terminals 252, and is used for their contacting.

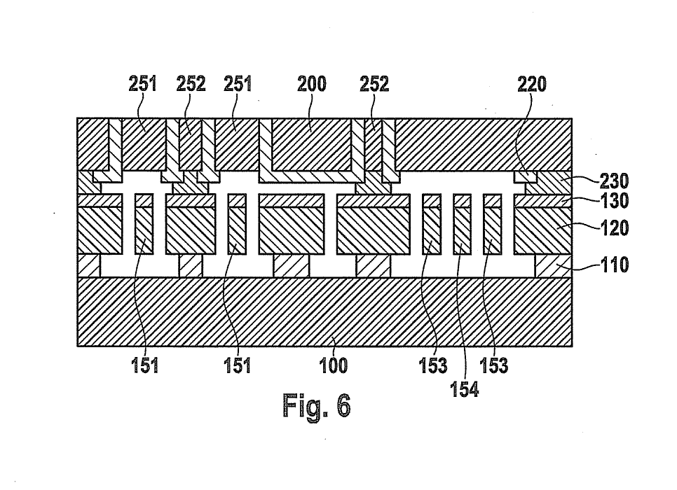

In addition, metallic layer 230 of cap substrate 200, together with metallic layer 130 of functional substrate 100, is used to connect to each other the two substrates 100, 200, within the scope of a wafer bonding method, in a mechanically stable manner (FIG. 6). By the connection of the two substrates 100, 200, a cavity or a plurality of cavities enclosing functional elements 151, 153, 154 are formed, which are hermetically sealed from the environment via layers 130, 230 that function as a sealing frame. Substrates 100, 200 are furthermore connected in such a way that an electrode 251 borders on a cavity in an area above a functional element 151.

To connect substrates 100, 200, a eutectic bonding process may be carried out, in which the two metallic layers 130, 230 form a eutectic alloy under the influence of temperature. Alternatively, it is possible to carry out thermal compression bonding, in which layers 130, 230 are connected to form a common layer by temperature influence and pressing together substrates 100, 200. However, for reasons of clarity, layers 130, 230 in FIGS. 6 and 7 are still shown as individual layers. With respect to the bonding method named, the materials of layers 130, 230 are appropriately matched to each other.

The connection of the two substrates 100, 200 is also carried out in a specified atmosphere at a specified (such as a very low) pressure, in order to set a specified pressure in the cavity (cavities) between the two substrates 100, 200. Because of the connection via the metallic layers 130, 230, there is no danger of gas being given off, so that the pressure, once it is set, does not undergo any further change. The connection via layers 130, 230 is also electrically conductive and, compared to a seal glass connection, is able to be implemented in a more space-saving manner (smaller width of the sealing frame).

After the connection of the two substrates 100, 200, substrate material is also removed on a backside surface of cap substrate 200 up to at least insulating layer 220. In this way, electrodes 251 defined by insulating layer 220 and terminals 252 are exposed on the backside surface as shown in FIG. 6, so that electrodes 251 and terminals 252 penetrate all the way through substrate 200 and its semiconductor material. The removal on the backside of the substrate may take place, for instance, by back grinding (for instance CMP chemical mechanical polishing). Functional substrate 100 may also be thinned backwards in an appropriate removal or grinding process.

Moreover, as shown in FIG. 7, an additional insulating layer 260 is applied over a large area onto the backside surface of cap substrate 200, and the latter is patterned within the scope of a lithographic patterning method, so that electrodes 251 and terminal 252 are, in turn, partially exposed. In this connection, saw marks may also be applied to layer 260 for cutting units apart. An additional metallic layer 270 is applied over a large surface onto the backside surface of substrate 200 and onto insulating layer 260 and is patterned lithographically, in order to provide electrodes 251 and terminals 252 with a metallization, via which electrodes 251 and terminals 252 may be contacted from the outside. After that, the cutting apart process may be carried out, whereby micromechanical component 300 is essentially finished.

Component 300 has three wiring planes which are formed by functional layer 120 covered by metallic layer 130, terminals penetrating through substrate 200 or through contacts 252, and metallic layer 270. Moreover, component 300 has a z rocker including functional element 151 and an oscillator structure including functional elements 153, 154, whose oscillating directions are indicated in FIG. 7 by arrows.

In the operation of the z rocker of component 300, the capacitance is measured between electrodes 251 and functional elements 151, that act as reference electrodes, a deflection of functional elements 151 manifesting itself in a change in capacitance. In this connection, functional elements 151 may be contacted via a terminal 252, that is assigned to the z-ROCKER, and via layers 230, 130, 120. In order to make possible a differential evaluation, functional elements 151 may be connected to one another for an oppositely directed deflection, as indicated in FIG. 7 with the aid of the different arrow directions. A comparable functioning comes about for the oscillating structure, in this case, the capacitance being measured between immobile functional element 154 and deflectable functional elements 153. Functional elements 153, 154, in this case, may be contacted via associated terminals 252 or via layers 230, 130, 120.

Because of the situation of electrodes 251 and terminals 252 in cap substrate 200 above micropattern 150, a low installation height of component 300 is made possible. The method is also based on only six lithographic patterning planes or lithographic patterning processes, whereby the method takes on a simple and cost-effective form. It further proves favorable that the rear thinning of cap substrate 200 (and, if necessary, also functional substrate 100) is carried out only after the connection of substrates 100, 200, so that the substrates are able to have a relatively large thickness in the preceding method steps.

The method explained with reference to the figures and micromechanical component 300 represent specific embodiments of the present invention. Furthermore, additional specific embodiments may be realized, which include additional modifications of the present invention. In particular, instead of the specified materials, other materials may be used.

A connection between a functional substrate and a cap substrate may, instead of via two metallic layers, also take place via one metallic layer applied onto the cap substrate, which is connected directly to a functional layer in a bonding method. One example that comes into consideration for this is a eutectic connection formation between the materials gold (metallic layer) and silicon (functional layer.

Electrodes and terminals in a cap substrate may alternatively be developed with the aid of a “through-silicon via” method. In this case, trenches are developed in the substrate, the trenches are lined using an insulating layer, and subsequently, the trenches are filled up using a conductive layer.

A micromechanical component may also be realized having a different number of functional elements. Furthermore, the production is possible of a component which has only one or more z rockers and no oscillating structure, the z rockers being able to be evaluated via electrodes and terminals of a cap substrate.

1-11. (canceled)

12. A method for producing a micromechanical component, the method comprising:
providing a first substrate;
developing a micropattem, on the first substrate, having a movable functional element;
providing a second substrate;
developing an electrode in the second substrate for capacitively recording a deflection of the functional elements; and
connecting the first substrate and the second substrate, wherein a closed cavity is formed which encloses the functional element, and the electrode bordering on the cavity in an area of the functional element.

13. The method of claim 12, wherein the development of the electrode includes the development of an insulating structure in the second substrate, which frames a substrate area in the second substrate.

14. The method of claim 12, wherein the micropattem is developed having a first metallic layer, wherein a second metallic layer is developed on the second substrate, and wherein the connecting of the first substrate and the second substrate occur via the first metallic layer and the second metallic layer.

15. The method of claim 12, wherein the connecting of the first substrate and the second substrate is carried out by one of the following processes: (i) eutectic bonding; and (ii) thermal compression bonding.

16. The method of claim 15, wherein, after the connecting of the first substrate and the second substrate, substrate material is removed on a backside surface of the second substrate to expose the electrode on the backside surface.

17. The method of claim 12, wherein, after the removal of the substrate material, a metallization is developed on the backside surface of the second substrate, which contacts the exposed electrode.

18. The method of claim 12, wherein a terminal is developed in the second substrate, via which an electrical connection is produceable all the way through the second substrate to the micropattern.

19. A micromechanical component, comprising:
a first substrate, wherein the first substrate has a micropattern having a movable functional element; and
a second substrate connected to the first substrate, wherein the first substrate and the second substrate are connected to each other so that the functional element is enclosed by a closed cavity, wherein the second substrate has an electrode for capacitively recording a deflection of the functional element, and wherein the electrode borders on the cavity in an area of the functional element.

20. The micromechanical component of claim 19, wherein the electrode is contactable on a backside surface of the second substrate.

21. The micromechanical component of claim 19, wherein the first substrate and the second substrate are connected to each other by a metallic layer.

22. The micromechanical component of claim 21, wherein the second substrate has a terminal, penetrating through the second substrate, for producing an electrical connection to the micropattern.
